(19) United States
(12) Patent Application Publication
(10) Pub. No.: US 2015/0088438 A1
(43) Pub. Date: Mar. 26, 2015

(54) RATIO METRIC CURRENT MEASUREMENT

(71) Applicant: James J. Kinsella, Pleasant View, TN (US)

(72) Inventor: James J. Kinsella, Pleasant View, TN (US)

(21) Appl. No.: 14/037,922

(22) Filed: Sep. 26, 2013

(51) Int. Cl. G01R 35/00; G01R 27/02; G01R 19/00

(52) U.S. Cl. CPC G01R 35/005; G01R 19/0092; G01R 27/02
USPC 702/58; 702/64

(57) ABSTRACT

The total current flow in a given electric circuit path is estimated by measuring the current in a second parallel current path and applying a ratio of the conductivity of the main and secondary path. Earth leakage current is measured by passing three wires through a toroid so as to detect differential current flow. Each wire is a conduction path wire parallel to each phase cable. The relative harmonic content between the fundamental and higher frequency components of a load current are calculated using a conduction path parallel to the main power cables.

### TECHNICAL FIELD

The present disclosure relates in general to electric motor control and distribution of electrical energy and more particularly to a ratio metric current measurement.

### BACKGROUND

The measurement of AC electrical current is frequently required in the electric motor industry. Some uses of electrical current measurement include metering, short circuit protection, motor overload protection, branch circuit overload, harmonic measurement, and the like. Of particular interest are current measurements of high bandwidth currents in electric motors and/or high current levels that are expensive to measure using conventional current measurement schemes.

There are many methods of making these current measurements. These include precision shunt resistors, current transformers, Hall Effect devices, resistive measurement, and the like.

With all of these methods, the size and cost of the current measurement device goes up geometrically with the magnitude of the measured current and the bandwidth of that current measurement.

### BRIEF DESCRIPTION OF DRAWINGS

For a more complete understanding of the present disclosure, reference is made to the following description, taken in conjunction with the accompanying drawings, wherein like reference numerals represent like parts, in which:

FIG. 1 illustrates a main load cable and a high impedance wire connected at two points of the main load cable;

FIG. 2 illustrates an assembly having one phase of what would be a three phase branch circuit with the main load cable and the high impedance wire connected with a main power supply and a load such as an electric motor;

FIG. 3 illustrates an assembly with a toroid through which high impedance wires carrying the ratio currents from each phase of a three phases are passed.

### DETAILED DESCRIPTION

### Known Parallel Impedances

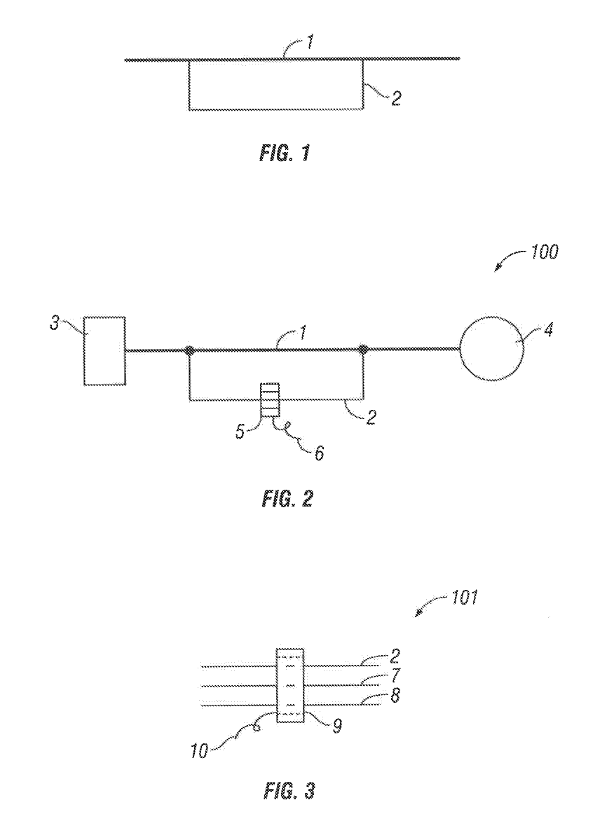

FIG. 1 illustrates a main load cable 1 and a high impedance wire 2 connected at two points of the main load cable 1 such that any current flow will divide proportional to the impedances of the two paths per Ohms Law. If electrical current is divided between two or more parallel conduction paths, that current will divide according to the respective impedances of these paths. That division will remain consistent as long as the relative impedances remain consistent. Thus the current in the sum of the parallel paths can be calculated by knowing the current in one path and the impedances of the other parallel paths.

In one implementation, a secondary higher impedance path would be made in parallel to a main current carrying path. The secondary path and the main path could have a know impedance ratio or a known current could be driven through both paths and the impedance ratio could be calibrated via the known total current and stored. Similarly, a calibration step could be employed wherein the impedance of one of the paths could be modified to achieve a known impedance ratio. A further calibration implementation is to induce a known current into the main low impedance connection where the high impedance current would always reflect that value or ratio. For an actual application, the calibration could be made directly from a known motor current. A further option is to begin with an estimated ratio, then, with a suitable algorithm, learn the correct ratio during commissioning or in service.

Once the impedance or current division ratio is known, calibrated, or learned, the total current in the sum of the paths can be ascertained by measuring the current in the secondary path. This has the advantage of allowing the use of smaller and less expensive current measurement elements.

### Unknown Parallel Impedances

In some current measurements, the important measurements to be made are the high frequency components of the current. In many cases, these high frequency components are in a known ratio to the fundamental AC current. This is true for detecting arc faults, pump cavitation, and motor bearing failure, among others. In this case, the current spectrum is separated into the various frequencies and the high frequency components are compared, in ratio, to the mains fundamental.

This means that a parallel conduction path contains all of the information required to detect the required event even though all of the current does not flow through the current sensor. In fact, it is unnecessary to know the precise division of the current between the parallel paths, since each path contains the same ratio metric information.

The advantages of this measurement are several. First, smaller and less expensive current sensors may be used to gather the same information as conventional measurement techniques. Second, smaller sensors generally have a higher bandwidth than larger sensors. This is especially true of Hall Effect magnetic path nulling sensors (LEM's). Third, the power supply requirements of the sensors can be reduced. This is because LEM nulling type sensors consume power in proportion to the measured current.

In one implementation of this technology, a secondary path is made parallel to the main current path. A small sensor, a LEM or similar, is positioned in the secondary path. The current is measured in this secondary path. This current is expanded into its various frequency components. A detection algorithm then compares the frequencies of interest in ratio to the magnitude of the fundamental.

### Motor Branch Circuit Protection

FIG. 2 shows an assembly 100 having one phase of what would be a three phase branch circuit with the main load cable 1 and the high impedance wire 2 connected with a main power supply 3 and a load 4 such as an electric motor. A sensor 5 on the high impedance wire 2 is used for measuring a current proportional to the load current. This current is observed through output 6. A processor (not shown) may be used in conjunction with the sensor to perform the current measurements and calculations.

This measurement lends itself to providing motor overload protection either by protection thresholds or more complex motor modeling techniques. The current measured in FIG. 2 may be used for motor and installed cable thermal protection as well as an indicator of motor load and may also be used for metering and monitoring.

Should a fault occur in the branch circuit, this current may be used for measuring the rate of rise of line current and sending a trip signal to a circuit breaker. Cable or motor insulation faults are common and occur through failure of insulation. These faults are progressive in the sense that insulation fails over a period of time. When detected early, costly repairs and down time are minimized.

FIG. 3 shows an assembly 101 with three high impedance wires 2, 7, and 8, from a three phase application of FIG. 1, passed through a toroid 9. In the absence of a current path to ground, the instantaneous value of three balanced line currents is zero. Thus by passing all three phase currents through the toroid 9 and measuring the out of balance (known as the differential or earth leakage current), the output 10 reflects the degree of current leakage to ground or the degree of imbalance in the line currents. The output 10 is processed by a variety of electronic means so that the equipment user can respond accordingly.

Leakage currents to ground can be relatively constant when caused by insulation degradation or may be relatively intermittent in the event of arcing in cables to ground or within the motor. When such arcing occurs, the output, which contains the full spectrum of line current frequencies, allows for further processing to provide information regarding the system arc energy.

Although the present disclosure has been described in detail with reference to particular embodiments, it should be understood that various other changes, substitutions, variations, alterations, and modifications may be ascertained by those skilled in the art and it is intended that the present disclosure encompass all such changes, substitutions, variations, alterations, and modifications as falling within the spirit and scope of the appended claims. Moreover, the present disclosure is not intended to be limited in any way by any statement in the specification that is not otherwise reflected in the appended claims.

What is claimed is:

1. A method of measuring electric current, comprising:
introducing a current in a main conducting path and a secondary path in parallel with the main conducting path;
sensing the current in the secondary path;
calculating a total current in the main conducting path and the secondary path from an impedance ratio of the main conducting path and the secondary path.

2. The method of claim 1, wherein the impedances of the main conducting path and the secondary path are known.

3. The method of claim 1, wherein the ratio of the impedances of the main conducting path and the secondary path are adjusted to a known condition.

4. The method of claim 1, further comprising:
calibrating the ratio of the impedances of the main conducting path and the secondary path.

5. The method of claim 4, wherein the calibration is performed by driving a known current through the main conducting path and the secondary path.

6. The method of claim 4, further comprising:
estimating the ratio of the impedances of the main conducting path and the secondary path from test data.

7. The method of claim 6, wherein the ratio is refined by a learning process during commissioning or in service.

8. The method of claim 1, further comprising:
storing the ratio in a memory.

9. The method of claim 1, further comprising:
expanding the current in the secondary path into its various frequency components;
comparing high frequency current components in the secondary path to a fundamental AC current.

10. The method of claim 9, further comprising:
detecting any one of an arc fault, a pump cavitation, and a motor bearing failure from the comparison.

11. The method of claim 1, further comprising:
coupling the sensor to an overload relay.

12. The method of claim 1, further comprising:
coupling the sensor to a circuit breaker.

13. The method of claim 1, further comprising:
coupling the sensor to a motor or power distribution branch circuit protective system.

14. The method of claim 1, further comprising:
measuring a rate of rise of fault currents.

15. The method of claim 1, further comprising:
introducing the current into three secondary paths;
coupling the three secondary paths to a toroid;
measuring a differential current of the three secondary paths at the toroid.
